(19) United States
(12) Patent Application Publication
(10) Pub. No.: US 2013/0256810 A1
(43) Pub. Date: Oct. 3, 2013

(54) Semiconductor Device and Method for Manufacturing the Same

(71) Applicants: Haizhou Yin, Poughkeepsie, NY (US); Wei Jiang, Beijing (CN)

(72) Inventors: Haizhou Yin, Poughkeepsie, NY (US); Wei Jiang, Beijing (CN)

(21) Appl. No.: 13/512,329

(22) PCT Filed: Apr. 9, 2012
(86) PCT No.: PCT/CN2012/000464

§ 371 Date: May 26, 2012

(30) Foreign Application Priority Data
Mar. 29, 2012 (CN) 201210088153.7

(51) Int. Cl. H01L 29/06; H01L 21/76

(52) U.S. Cl. 257/401; 438/424; 257/E29.005; 257/E21.546

(57) ABSTRACT

The present invention discloses a semiconductor device, which comprises: a first epitaxial layer on a substrate; a second epitaxial layer on the first epitaxial layer, wherein a MOSFET is formed in an active region of the second epitaxial layer; and an inverted-T shaped STI formed in the first epitaxial layer and the second epitaxial layer and surrounding the active region. In the semiconductor device and the method for manufacturing the same according to the present invention, the double epitaxial layers are selectively etched to form an inverted-T shaped STI, which effectively reduces the leakage current of the device without reducing the area of the active region, thereby improving the device reliability.

### CROSS-REFERENCE TO RELATED APPLICATION

This application is a National Stage application of, and claims priority to, PCT Application No. PCT/CN2012/000464, filed on Apr. 9, 2012, entitled “Semiconductor Device and Method for Manufacturing the Same”, which claimed priority to Chinese Application No. 201210088153.7, filed on Mar. 29, 2012. Both the PCT Application and Chinese Application are incorporated herein by reference in their entireties.

### FIELD OF THE INVENTION

The present invention relates to a semiconductor device and a method for manufacturing the same, and in particular, to a MOSFET having an inverted-T shaped shallow trench isolation formed by an epitaxial process and a method for manufacturing the same.

### BACKGROUND OF THE INVENTION

In the conventional bulk silicon CMOS, a pn junction is formed between the well region and the substrate, while a pn junction is also formed between the source and drain regions and the substrate in the MOSFET. These parasitic controlled silicon structures may cause a high leakage current between the power source and ground under certain conditions, thereby generating a latch-up effect. Especially under the logic circuit technology node of 0.25 μm, such parasitic latch-up effect greatly hinders further improvement of the semiconductor device performance.

One of the methods that can effectively prevent the latch-up effect is to adopt the Shallow Trench Isolation (STI) technique. The parasitic electrical connection that might be formed between the NMOS and PMOS devices can be discontinued by the shallow trench isolation that is insulated and filled with, for example, silicon oxide, thereby increasing the device reliability. In addition, as compared to the local oxidation of silicon process (LOCOS), the STI occupies a shorter width of the channel and has a smaller isolation pitch, thus it will not erode the active region, thereby avoiding the Bird's Beak effect of LOCOS. Moreover, the isolation structures formed by the STI are mostly located under the surface of the substrate, which will facilitate the planarization of the entire surface of the device.

However, with the continuous reduction in the feature size of the device, the insulating performance of the STI itself also degrades sharply. It has become difficult for conventional materials, shapes and structures to provide good insulation between the devices with small size. Therefore, how to control the leakage current between the devices has become an important issue that hinders development of the devices with small size.

In this case, there is an urgent need for a novel STI that can effectively reduce the leakage current of the devices while not reducing the area of the active region, a MOSFET using such an STI and a method for manufacturing the same.

### SUMMARY OF THE INVENTION

In view of the above, an object of the present invention is to provide a MOSFET having an inverted-T shaped shallow trench isolation formed by an epitaxial process and a method for manufacturing the same so as to effectively reduce the leakage current of the device while not reducing the area of the active region.

To achieve the above goal, the present invention provides a semiconductor device, which comprises: a first epitaxial layer on a substrate; a second epitaxial layer on the first epitaxial layer, wherein a MOSFET is formed in an active region of the second epitaxial layer; and an inverted-T shaped STI formed in the first epitaxial layer and the second epitaxial layer and surrounding the active region.

Preferably, the width of the STI in the first epitaxial layer is greater than that in the second epitaxial layer. Preferably, a part of the STI in the first epitaxial layer extends into the active region to be formed under the source and drain regions in the second epitaxial layer.

Preferably, the material of the first epitaxial layer is different from that of the substrate and/or the second epitaxial layer. Preferably, the material of the first epitaxial layer includes SiGe.

The present invention also provides a method for manufacturing a semiconductor device, which comprises: forming a first epitaxial layer and a second epitaxial in sequence on a substrate; etching the second epitaxial layer to form an opening of the second epitaxial layer; etching the first epitaxial layer to form an opening of the first epitaxial layer, the opening of the first epitaxial layer and the opening of the second epitaxial layer constituting an inverted-T shaped trench; filling the inverted-T shaped trench with an insulating material to form an STI, wherein an active region is formed by a part of the second epitaxial layer surrounded by the STI; and forming a MOSFET in the active region of the second epitaxial layer.

Preferably, the width of the opening of the first epitaxial layer is greater than the width of the opening of the second epitaxial layer. Preferably, a part of the STI in the first epitaxial layer extends into the active region to be formed under the source and drain regions in the second epitaxial layer.

Preferably, the material of the first epitaxial layer is different from that of the substrate and/or the second epitaxial layer. Preferably, the material of the first epitaxial layer includes SiGe.

Preferably, etching the second epitaxial layer comprises: forming a hard mask layer on the second epitaxial layer; photoetching/etching the hard mask layer to expose the second epitaxial layer, so as to form a hard mask layer pattern which has a hard mask layer opening; and anisotropically etching the second epitaxial layer with the hard mask layer pattern as a mask to expose the first epitaxial layer, so as to form the opening of the second epitaxial layer. Preferably, the hard mask layer comprises at least a first hard mask layer of oxide and a second hard mask layer of nitride.

Preferably, etching of the first epitaxial layer is performed by wet Etching.

Preferably, the filled insulating material includes spin-on glass.

In the semiconductor device and the method for manufacturing the same according to the present invention, the double epitaxial layers are selectively etched to form an inverted-T shaped STI, which effectively reduces the leakage current of the device without reducing the area of the active region, thereby improving the device reliability.

### BRIEF DESCRIPTION OF THE DRAWINGS

The technical solutions of the present invention will be described in detail below with reference to the accompanying drawings, wherein:

FIGS. 1-6 are schematic cross-sectional views of the various steps of a method for manufacturing a MOSFET according to the present invention.

### DETAILED DESCRIPTION OF THE PREFERRED EMBODIMENTS

The features and technical effects of the technical solutions of the present invention will be described in detail below with reference to the drawings and in combination with exemplary embodiments. A MOSFET having an inverted-T shaped shallow trench isolation formed by an epitaxial process and a method for manufacturing the same are disclosed. It shall be noted that like reference signs denote like structures, and the terms used in the present invention, such as “first”, “second”, “above”, “below”, and the like, can be used to modify various device structures or manufacturing processes. Unless specified otherwise, such modification does not imply the spatial, sequential or hierarchical relationships between the device structures or manufacturing processes.

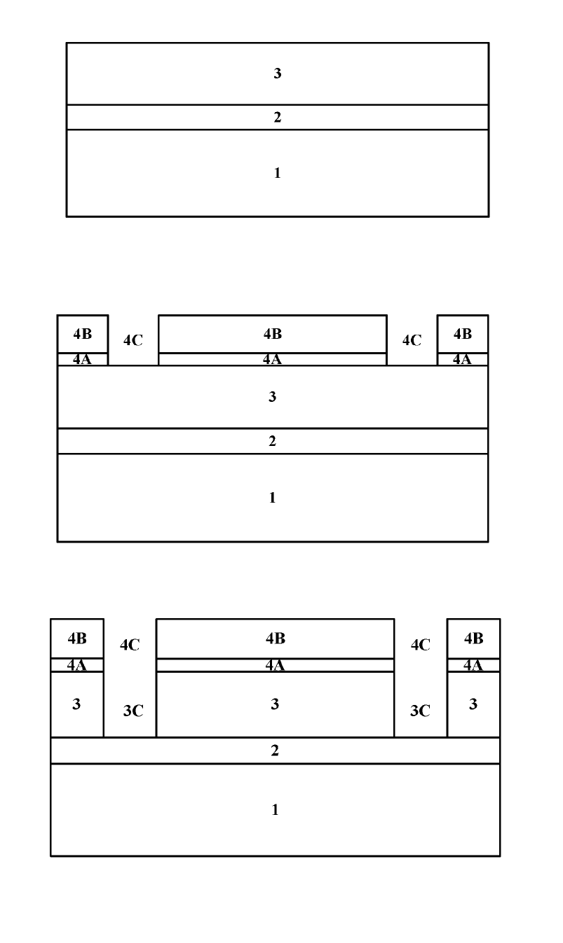

The various steps of the method for manufacturing the MOSFET according to the present invention will be described in detail below with reference to the schematic cross-sectional views of FIGS. 1-6.

Referring to FIG. 1, a first epitaxial layer 2 and a second epitaxial layer 3 are formed in sequence on a substrate 1.

The substrate 1 may be provided and appropriately selected according to the requirements for the application of the device. The material used as the substrate 1 may comprise one of monocrystal silicon (Si), Silicon On Insulator (SOI), monocrystal germanium (Ge), Germanium On Insulator (GeOI), strained silicon (strained Si), silicon germanium (SiGe), compound semiconductor materials, such as gallium nitride (GaN), gallium arsenide (GaAs), indium phosphide (InP), and indium antimonide (InSb), and carbon-based semiconductor, such as graphene, SiC, and carbon nanotube, etc.. Preferably, the substrate 1 may be bulk silicon, e.g. a Si wafer, so as to be compatible with the CMOS technology to apply to a digital logic integrated circuit.

The first epitaxial layer 2 is epitaxially grown on the substrate 1 by means of a conventional epitaxial method, such as PECVD, MBE and ALD. Preferably, the material of the first epitaxial layer 2 may be, for example, one of SiGe, and SiC, etc., which is different from the material of the substrate 1, so that a stress can be generated due to the different crystal lattice structures between the first epitaxial layer 2 and the substrate 1, thereby increasing the carrier mobility in the channel to be formed later of the device and further enhancing the driving capability of the device. Preferably, the material of the first epitaxial layer 2 may be selected to have a greater etching selection ratio with respect to the lower substrate 1 or the upper other materials. Preferably, SiGe may be used as the material of the first epitaxial layer 2. The first epitaxial layer 2 has a first thickness t1, which is, for example, between about 10 to 200 nm.

Similarly, the second epitaxial layer 3 is epitaxially grown on the first epitaxial layer 2 by using a conventional epitaxial method, such as PECVD, MBE, ALD, and thermal decomposition, etc.. The material of the second epitaxial layer 3 is different from that of the first epitaxial layer 2 so as to increase the etching selection ratio in the later etching process. Preferably, the material of the second epitaxial material 3 may be the same as that of the substrate 1, such as Si, so as to form the channel region, the source and drain regions of the device. The second epitaxial layer 3 has a second thickness t2, which is greater than t1 and is, for example, between about 300 to 1000 nm. Preferably, an in-situ doping may be synchronously performed during the formation of the second epitaxial layer 3, or an ion implantation doping may be performed after the formation of the second epitaxial layer 3 to form an active region doping of the n- or p-devices.

Referring to FIG. 2, a hard mask layer 4 is deposited on the second epitaxial layer 3, and is photoetched/etched to form a hard mask layer pattern having an opening that exposes a part of the second epitaxial layer 3. The hard mask layer may be a single layer or multi-layer. Preferably, the hard mask layer includes at least a first hard mask layer 4A of oxide, e.g. silicon oxide, and a second hard mask layer 4B of nitride, e.g. silicon nitride, or oxynitride, e.g. silicon oxynitride. By using such stacked hard mask layer, the precision of the etched pattern can be well controlled, and the surface of the substrate to be etched and covered by the stacked hard mask layer can be well protected. As shown in FIG. 2, a photoresist (not shown) is spin coated and is exposed and developed to form a photoresist pattern. A hard mask layer opening 4C is formed by performing anisotropic etching in the hard mask layer 4A/4B by means of dry etching, such as plasma etching, using the photoresist pattern as a mask, until the second epitaxial layer 3 is exposed. At this time, the surface of the second epitaxial layer 3 is not over-etched due to the stacked structure of the hard mask layer, so the defect density of the surface is not increased. Although the opening 4C is shown as two sections in the cross-sectional view, it actually surrounds the active region of the device, namely, it is of a ring-shaped structure in the top view (not shown), for example, a rectangular ring frame. The opening 4C has a first width (i.e., a space between the inner and outer boundaries of the ring frame) W1, for example, between about 200 to 400 nm.

Referring to FIG. 3, the part of the second epitaxial layer 3 exposed in the opening is etched using the hard mask layer pattern as a mask until the first epitaxial layer 2 is exposed. Preferably, the second epitaxial layer 3 may be etched in an anisotropic manner by means of dry etching. When the material of the second epitaxial layer 3 is Si, a solution having good anisotropy used for wet etching, such as TMAH, may also be used for the etching. As shown in FIG. 3, an opening 3C is also formed in the second epitaxial layer 3, which has the same width W1 as the opening 4C.

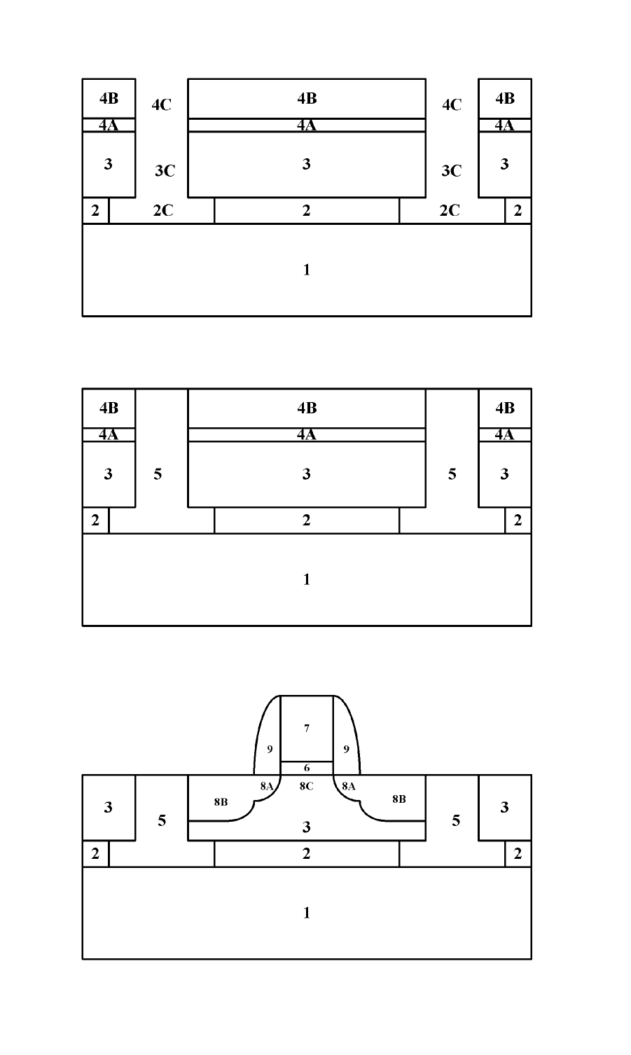

Referring to FIG. 4, the exposed first epitaxial layer 2 is etched to form an inverted-T shaped trench structure. Preferably, the first epitaxial layer 2 may be selectively etched by means of wet etching. When the material of the first epitaxial layer 2 is, for example, one of SiGe and SiC, which is different from the materials of the second epitaxial layer 3 and the substrate 1, a proper etching solution is selected, so that the etching rate of the first epitaxial layer 2 is higher than that of the second epitaxial layer 3, or the second epitaxial layer 3 is almost not etched. The proper etching solution includes a combination of hydrofluoric acid and oxidant with a volume ratio of, for example, 1:6. The oxidant includes, for example, one of oxydol, sulphuric acid and nitric acid. The working principle of the above is to oxidize the element (e.g. Ge and C, etc.) other than Si in the first epitaxial layer 2 into a corresponding oxide so as to be removed by etching using hydrofluoric acid. The etching rate can be controlled by adjusting the ratio of hydrofluoric acid to oxidant and the working temperature. As shown in FIG. 4, an opening 2C is formed in the first epitaxial layer 2. The opening 2C has a second width W2, which is greater than W1 and is, for example, between about 500 to 700 nm. Thus, the inverted-T shaped trench structure (3C/2C) as shown in FIG. 4 is formed. Preferably, the upper width W1 of the inverted-T shaped trench structure may be smaller than the lower width W2 of the inverted-T shaped trench structure.

It shall be noted that, although the openings of the epitaxial layers having different widths have been combined to form the inverted-T shaped trench in the above embodiments, other geometrical structures may also be used to form the inverted-T shaped trench. for example, the first epitaxial layer may be etched step by step, or different concentrations of the etching solution are selected to control the etching rate, so that the opening in the first epitaxial layer 2 itself can be formed as an inverted-T shape that is narrow at the top and wide at the bottom, while the opening in the second epitaxial layer 3 on the first epitaxial layer 2 is of the same width as the upper portion of the opening of the first epitaxial layer 2. Alternatively, the opening in the second epitaxial layer 3 itself may be formed as an inverted-T shape that is narrow at the top and wide at the bottom, while the opening in the first epitaxial layer 2 is of the same width as the lower portion of the opening of the second epitaxial layer 3. The present invention only enumerates some possible implementations for forming the inverted-T shape in the embodiments, but in fact, all of technological methods for forming the inverted-T shaped structure are possible, as long as the inverted-T shaped structure can be formed using such technological method to effectively reduce the leakage current of the device without reducing the area of the active region.

Referring to FIG. 5, an insulating material is filled into the inverted-T shaped trench structure to form an inverted-T shaped STI. For example, a spin-on glass (SOG) is filled into the inverted-T shaped trench structure 3C/2C by means of spin coating, or silicon oxide and/or silicon oxynitride are deposited in the trench by means of one of LPCVD, PECVD, HDPCVD, etc.. Then planarization is performed by CMP until the hard mask layer is exposed. The inverted-T shaped STI 5 is formed after annealing. Preferably, the upper width W1 of the STI 5 may be smaller than the lower width W2 the STI 5. Preferably, a part of the lower portion of the STI 5 may be within the range of the active region of the second epitaxial layer 3 and extend below the source and drain regions, thereby reducing the possible leakage current and improving the device reliability.

Referring to FIG. 6, the subsequent manufacturing of the MOSFET is completed in the active region of the second epitaxial layer 3 surrounded by the STI. The hard mask layer 4A/4B is removed by wet etching A gate stack comprising a pad oxide layer (e.g. silicon oxide, not shown), a gate insulating layer 6 (e.g. high k material), a gate conductive layer 7 (e.g. doped polysilicon, metal, metal alloy, metal nitride) is formed on the surface of the active region of the second epitaxial layer 3 by performing deposition and etching on the surface of the active region. A first ion implantation is performed on a source and drain using the gate stack as a mask to form lightly doped source and drain extension regions 8A. Gate spacers 9 made of silicon nitride are formed on the second epitaxial layer 3 on both sides of the gate stack. A second ion implantation is performed on the source and drain using the gate spacers 9 as a mask to form heavily doped source and drain regions 8B. A channel region 8C is composed of a part of the second epitaxial layer 3 between the source and drain regions 8A/8B. A self-alignment process is performed using a silicide on the source and drain regions 8B to form a metal silicide (not shown) so as to reduce the source and drain resistances. An interlayer dielectric layer (not shown) that is formed from a low-k material, such as silicon oxide, is formed on the entire device. The interlayer dielectric layer is etched to form a contact hole that directly reaches the metal silicide. The contact hole is filled with a metal to form a contact plug (not shown).

The finally formed MOSFET structure, as shown in FIG. 6, comprises: a substrate; a first epitaxial layer on the substrate; a second epitaxial layer on the first epitaxial layer, wherein source and drain regions and a channel region are formed in the active region in the second epitaxial layer and a gate stack is formed in the active region on the second epitaxial layer; and an inverted-T shaped shallow trench isolation (STI) formed in the first epitaxial layer and the second epitaxial layer and surrounding the active region. Preferably, the width (i.e., the lower width) of the STI in the first epitaxial layer is greater than the width (i.e., the upper width) of the STI in the second epitaxial layer. The materials and forming processes of the remaining components have been previously described in detail and will not be repeated any more here.

In the semiconductor device and the method for manufacturing the same according to the present invention, the double epitaxial layers are selectively etched to form an inverted-T shaped STI, which effectively reduces the leakage current of the device without reducing the area of the active region, thereby improving the device reliability.

Although the present invention has been illustrated with reference to one or more exemplary embodiments, it shall be understood by those ordinary skilled in the art that various appropriate changes and equivalents can be made to the device structure without departing from the scope of the present invention. In addition, many modifications that might be adapted to specific situations or materials can be made from the teaching disclosed by the present invention without departing from the scope thereof. Therefore, the present invention is not intended to be limited to the specific embodiments which are disclosed as preferred implementations to carry out the invention, but the disclosed device structure and the method for manufacturing the same will include all embodiments that fall into the scope of the present invention.

What is claimed is:

1. A semiconductor device, comprising:
a first epitaxial layer on a substrate;
a second epitaxial layer on the first epitaxial layer, wherein a MOSFET is formed in an active region of the second epitaxial layer; and
an inverted-T shaped STI formed in the first epitaxial layer and the second epitaxial layer and surrounding the active region.

2. The semiconductor device according to claim 1, wherein the width of the STI in the first epitaxial layer is greater than that in the second epitaxial layer.

3. The semiconductor device according to claim 2, wherein a part of the STI in the first epitaxial layer extends into the active region to be formed under the source and drain regions in the second epitaxial layer.

4. The semiconductor device according to claim 1, wherein the material of the first epitaxial layer is different from that of the substrate and/or the second epitaxial layer.

5. The semiconductor device according to claim 4, wherein the material of the first epitaxial layer includes SiGe.

6. A method for manufacturing a semiconductor device, comprising:
forming a first epitaxial layer and a second epitaxial in sequence on a substrate;
etching the second epitaxial layer to form an opening of the second epitaxial layer;
etching the first epitaxial layer to form an opening of the first epitaxial layer, the opening of the first epitaxial layer and the opening of the second epitaxial layer constituting an inverted-T shaped trench;
filling the inverted-T shaped trench with an insulating material to form an STI, wherein an active region is formed by a part of the second epitaxial layer surrounded by the STI; and
forming a MOSFET in the second epitaxial layer.

7. The method for manufacturing a semiconductor device according to claim 6, wherein the width of the opening of the first epitaxial layer is greater than the width of the opening of the second epitaxial layer.

8. The method for manufacturing a semiconductor device according to claim 7, wherein a part of the STI in the first epitaxial layer extends into the active region to be formed under the source and drain regions in the second epitaxial layer.

9. The method for manufacturing a semiconductor device according to claim 6, wherein the material of the first epitaxial layer is different from that of the substrate and/or the second epitaxial layer.

10. The method for manufacturing a semiconductor device according to claim 9, wherein the material of the first epitaxial layer includes SiGe.

11. The method for manufacturing a semiconductor device according to claim 6, wherein etching the second epitaxial layer comprises:
forming a hard mask layer on the second epitaxial layer;
photoetching/etching the hard mask layer to expose the second epitaxial layer, so as to form a hard mask layer pattern which has a hard mask layer opening; and
anisotropically etching the second epitaxial layer with the hard mask layer pattern as a mask to expose the first epitaxial layer, so as to form the opening of the second epitaxial layer.

12. The method for manufacturing a semiconductor device according to claim 11, wherein the hard mask layer comprises at least a first hard mask layer of oxide and a second hard mask layer of nitride.

13. The method for manufacturing a semiconductor device according to claim 6, wherein etching of the first epitaxial layer is performed by wet etching.

14. The method for manufacturing a semiconductor device according to claim 6, wherein the filled insulating material includes spin-on glass.
